(19) United States
(12) Patent Application Publication
(10) Pub. No.: US 2007/0227587 A1
(43) Pub. Date: Oct. 4, 2007

(54) Photoelectric Cells Utilizing Accumulation Barriers For Charge Transport

(76) Inventor: Kevin Michael Walsh, Atlanta, GA (US)

Correspondence Address: Kevin Walsh, P.O. Box 170476, Atlanta, GA, 30317, US

(21) Appl. No.: 11/695,001

(22) Filed: Mar. 31, 2007

Related U.S. Application Data
(60) Provisional application No. 60/788,285, filed on Mar. 31, 2006.

(51) Int. Cl. H01L 31/00

(52) U.S. Cl. 136/252

(57) ABSTRACT

The invention describes a means for electrically contacting the active semiconductor in a solar cell through the use of an accumulation barrier. A heavily-doped, wide-gap semiconductor serves as the contacting material. The carrier band of the contact lies at a substantially higher potential energy than that of the corresponding band of the absorber and an accumulation barrier at the contact interface is thus produced. This type of contact presents several advantages, including the ability to use an all-intrinsic absorber, the formation of a low resistance ohmic contact and providing for a large, temperature independent built-in potential across the absorber.

### CROSS-REFERENCE TO RELATED APPLICATIONS

The application claims priority to U.S. Provisional Application Ser. No. 60/788,285 entitled “P-i-N tunneling Junction Photovoltaic Cell,” filed on Mar. 31, 2006.

### BACKGROUND OF THE INVENTION

1. Field of the Invention

The present invention relates to a photovoltaic devices composed of semiconductors as the active light absorbing materials, and more particularly to a photovoltaic devices in which a means for contacting the active absorbers is provided that results in high photoelectric conversion efficiencies.

2. Related Background Art

The operation of most photovoltaic cells is dependant upon the existence of a electric field (i.e. a built-in field that is present under dark, equilibrium conditions) within an active, light-absorbing semiconductor. The field is created by providing for a material that has an excess of mobile electrons at a relatively high potential energy in contact with a second material having electron vacancies at a low potential energy. At equilibrium, charge transfer between the two materials creates a build-up of space charge and an internal electric field. When irradiated under an open circuit, the built-in field accelerates photogenerated electrons and holes in opposing directions, altering the electron chemical potential on each side of the field. The built-in field is effectively the driving force that propels the photogenerated carriers out of the absorbing semiconductor and into an external circuit.

The electric field may be present solely within the active absorber, e.g. the p-n junction of crystalline silicon cells or it may be partially located external to the active semiconductor. Examples of the latter devices include the heterojunction cells CdS/CdTe and (AI,Ga)As/GaAs. Part of the charge that creates the electric field in heterojunction cells is resident within a wide-gap semiconductor that does not act as the primary absorber of light. The carrier concentration in the active absorber is made lower than that of the wide-gap material so that the change in electric potential occurs mostly within the absorber. It is also important to minimize or eliminate barriers at the heterojunction interface, since barriers will results in increased carrier recombination losses due to a build-up of photogenerated charge in the barrier region.

Other prior art cells types include the metal-insulator-semiconductor (MIS) and semiconductor-insulator-semiconductor (SIS) junctions (for example U.S. Pat. No. 4,117,506). These junctions consist of a doped absorber that is contacted on one side with either a metal or degenerate semiconductor, and having a very thin insulator placed between the contact and absorber. The metal (or degenerate semiconductor) contact produces a depletion of majority carriers (or equivalently stated, an accumulation of minority carriers) adjacent to the contact interface. This junction is commonly referred to as a Schottky barrier. The built-in field of the absorber exists within the majority carrier depleted region. The thin insulator serves both to reduce charge recombination at the interface and to increase the built-in field through the placement of static charge within the insulator.

While existing photovoltaic devices have proved to be a reasonably efficient means of converting solar radiation into electrical current, any means for improving the output power of these photovoltaic devices is most desirable, in the interest of reducing the cost and expanding the production of environmentally benign solar electricity.

### SUMMARY OF THE INVENTION

In the prior art examples, the absorber is doped to some extent by the addition of electrically-active impurities to create mobile charge carriers. At equilibrium the absorber is at least partially depleted of carriers. It is this depletion of carriers that creates the necessary internal electric field. The invention is essentially a means of electrically contacting the active absorber in a solar cell in such a way that part or all of the built-in field exists due to carrier accumulation at the contacting interface. Contacting the absorber in this way produces both a large electric field within the absorber and a low resistance contact. Furthermore, the invention eliminates the need for the absorber to be carrier depleted and may in fact be incorporated in a wholly intrinsic form. This last feature presents a particular advantage when the absorber has superior carrier properties in its undoped state.

The accumulation of carriers at the absorber contact arises due to the placement a heavily-doped, wide-gap semiconductor (hereafter referred to as a WGS) adjacent to the absorber. The carrier band of the WGS must lie at a substantially higher potential energy than the corresponding band of the absorber (i.e. there is a carrier band offset at the interface). This excess potential means that there will be a barrier to carrier transport across the interface for charge originating from within the absorber. However, the excess potential also produces charge accumulation on the absorber side of the interface. The combination of high carrier concentration in the WGS with charge accumulation at the absorber interface permits efficient carrier transport through this barrier via a tunneling or thermally-assisted tunneling mechanism.

This type of absorber contact presents several advantages with respect to photoelectric conversion efficiency, including:
A low resistance ohmic contact with the absorber.
A large field strength within the absorber corresponding to a potential change equal to the full width of the absorber band gap.
A built-in field strength that is in a practical sense independent of the cell temperature.
A reduced leakage current under load, due to the negligible minority carrier concentrations in a WGS.
The ability to use an undoped, intrinsic absorber, with associated enhanced carrier lifetimes and mobilities.

### BRIEF DESCRIPTION OF THE SEVERAL VIEWS OF THE DRAWING

FIG. 1 is a cross section of a “P⁺-i-N⁺” solar cell using an amorphous silicon hydride (a-Si:H) absorber. The wide bandgap semiconductors p⁺-CdS and n⁺-ZnS represent the tunneling contacts with intrinsic a-Si:H.

FIG. 2 is an equilibrium band diagram of the a-Si:H “P⁺-i-N⁺” solar cell shown in FIG. 1.

FIG. 3 is an equilibrium band diagram of a CdTe “P⁺-i-N⁺” solar cell. The wide bandgap semiconductors p⁺-CdS and n⁺-ZnS represent the tunneling contacts with intrinsic CdTe.

FIG. 4 is an equilibrium band diagram of a crystalline Si “P⁺-p-n-N⁺” solar cell. The wide bandgap semiconductors p⁺-ZnO and n⁺-ZnS represent the tunneling contacts with the crystalline Si.

### DETAILED DESCRIPTION OF THE INVENTION

The tunneling contact may be applied to any solar cell utilizing a semiconductor as the light absorbing material, including materials such as crystalline silicon and amorphous silicon hydride, amorphous (Si,Ge):H alloys, cadmium telluride, Cu(In,Ga)(Se,S) (CIGS) alloys and GaAs alloys. Several specific embodiments of the invention are described below.

### EXAMPLE 1

### Amorphous Silicon Hydride (a-Si:H) Absorber

A schematic representation of one embodiment of the invention in which the absorber is amorphous silicon is shown in FIG. 1. The cell's photoactive region may be described as a modified p-i-n junction. A p-i-n (or n-i-p) junction consists of an extended junction, formed by placing an intrinsic (i) semiconductor layer between p- and n-layers of the same or similar semiconductors. The potential drop across the intrinsic layer is equal to the difference between the work function in the p- and n-layers. In the ideal case, the intrinsic layer contains relatively little space charge. Where this is true, the electric field strength is nearly uniform through the bulk absorber layer and varies inversely with the thickness of the i-layer. The p-i-n junction is usually found in solar cells in which the absorber is a-Si:H.

The modified p-i-n cell illustrated in FIG. 1 uses intrinsic a-Si:H (i-a-Si:H) as the active absorber. The i-a-Si:H is placed between a pair of WGS's. The semiconductors suitable for use as the WGS may be chosen based upon the their known or predicted properties including the ability to be doped to high carrier concentrations. The WGS carrier band must also lie at a potential energy (with respect to the carrier) that is substantially greater than that of the active absorber it contacts. In the example of FIG. 1 the WGS's are p⁺-CdS (Appl. Phys. Lett. 1968; 12(10): 339-341) as the front-side tunneling contact and n⁺-ZnS (J. Appl. Phys. 1990; 7: 1714-1719) as the rear contact. This junction configuration may be symbolized as “P⁺-i-N⁺”. Also shown are the two cell electrodes, consisting of a transparent conducting oxide (TCO) on the front side and metal contact on the back, and a glass superstrate to complete the working device.

Parameters such as the thickness of each cell layer and method of deposition/fabrication are not essential to the understanding of the utility of the invention. These parameters may be determined by application of existing knowledge in the art and science of solar cell design. For example, it is known that a single i-a-Si:H layer thickness should generally not exceed about one micrometer, in the interest of minimizing carrier transit times and reducing photodegradation due to the Staebler-Wronski effect. Likewise, it also is known that front-side wide bandgap semiconductors usually should be made just sufficiently thick to reduce or eliminate the occurrence of pinholes and provide adequate conductivity, as an excessively thick layer can reduce the amount of incoming light reaching the absorber layer.

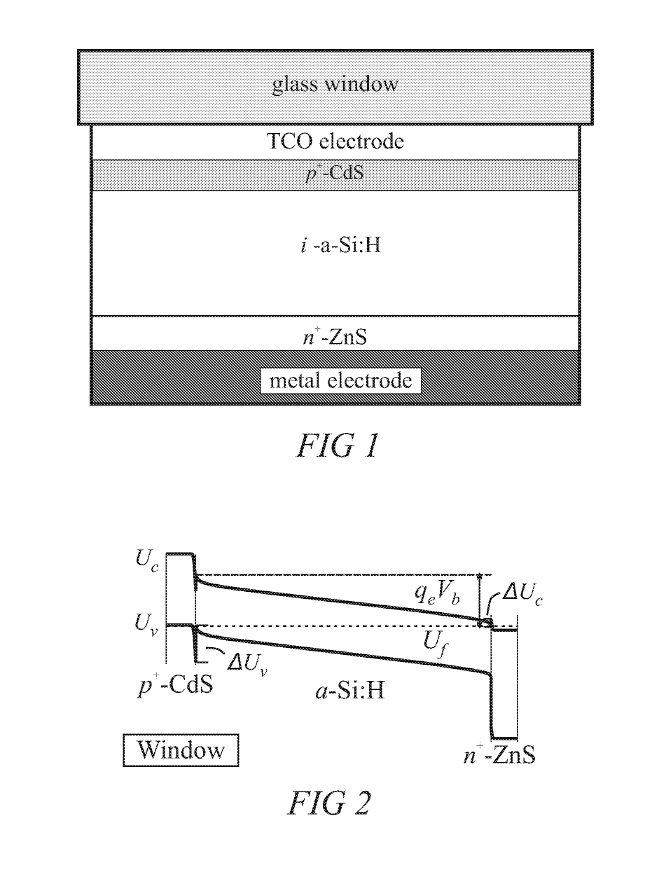

The carrier bands of p⁺-CdS and n⁺-ZnS are significantly offset in potential energy with respect to the corresponding bands in the i-a-Si:H absorber. In FIG. 2 is shown the equilibrium band diagram of the photoactive layers of the cell of the a-Si:H P⁺-i-N⁺ junction. The diagram illustrates the preferred features of the junction, including carrier band offsets “ΔUᵥ and ΔU_{c}” and a Fermi level “U_{f}” location inside the band edges of the WGS's due to their high carrier concentrations. Also shown is the large built-in potential across the absorber “qₑV_{b}”. These factors combine to produce high equilibrium carrier concentrations at the contact surfaces of the i-a-Si:H. In the example shown, the concentration of accumulated carriers at the interface are sufficient to cause the Fermi level to cross through the mobility band edges of i-a-Si:H.

The Fermi should lie close enough to the WGS band edge of the to give an adequate tunneling probability (approximately within 5 kT of the band edge), and most preferably should be lying within the band edge as illustrated in FIG. 2. Under these circumstances there is found both a large density of available states and a large field strength at the interfaces. Charge transfer across the interface may then occur readily via tunneling. The large field strength also reduces carrier recombination by rapidly sweeping photogenerated “minority” carriers away from the interfaces and toward the opposing contacts. This latter effect is particularly important on the front-side of the junction where much of the oncoming light is absorbed. In the example given, photogenerated electrons are rapidly swept away from the front p⁺-CdS/i-a-Si:H interface into the bulk i-a-Si:H, even while the cell is operating under load. This arrangement is in contrast to typical prior art designs of a-Si:H solar cells. For example, in U.S. Pat. No. 4,109,271 an intrinsic a-Si:H that is contacted with p-type a-(Si,C):H at the front-side for hole collection and n-type a-Si:H at the rear electron collection. There is a low equilibrium carrier concentration at both of the i-a-Si:H interfaces in this type of junction. Accumulation of non-equilibrium charge in these regions will result in excessive carrier recombination. It is for this reason that an effort is made to minimize band offsets at the interfaces, hence the choice of a-(Si,C):H and a-Si:H as the absorber contacts.

The operating parameters of the P⁺-i-N⁺ junction of FIGS. 1 and 2 were simulated using a computer program (AMPS-1 D) and the results were compared with those of a contemporary a-Si:H p-i-n junction. The simulation is described in J. Phys. D: Appl. Phys. 2007; 40: 1007-1009, which is incorporated by reference herein. It was found that the junction has both a large built-in field and significantly reduced carrier recombination rates. A 25% improvement in conversion efficiency was found for the simulated P⁺-i-N⁺ junction relative to the p-i-n junction.

Another important advantage of the invention is that the built-in field is independent of temperature across a normal operating temperature range. This is because the Fermi levels in the WGS's are not expected to change due to their large energy band gaps and high carrier concentrations. Consequently the built-in field remains equal to the potential change across the full width of the a-Si:H band gap at all normal operating temperatures. Whereas in conventional solar cells the built-in field is dependant on carrier depletion within the absorber. The smaller band gap and lower carrier concentrations in the absorber means that the depletion potential is reduced with increasing temperature. This loss of internal field strength is the most important factor in the reduction in the power output of conventional cells with increasing temperature, usually quoted as a cell's (or module's) temperature coefficient.

### EXAMPLE 2

### Cadmium Telluride (CdTe) Absorber

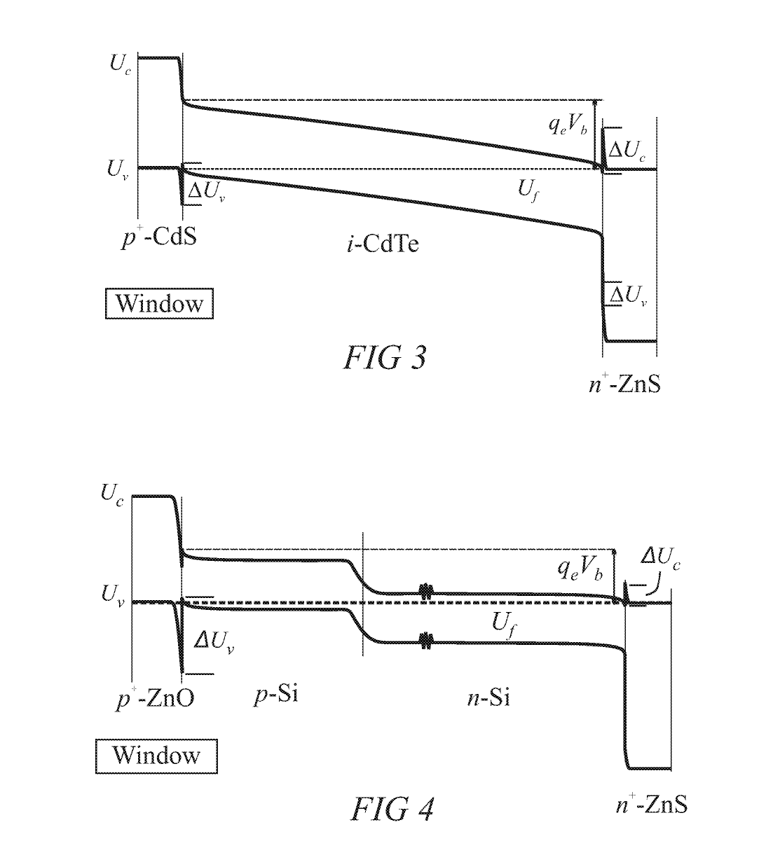

FIG. 3 illustrates, in the form of an equilibrium band diagram, the relevant sections of a P⁺-i-N⁺ solar cell that uses intrinsic CdTe as the active absorber. The cell makes use of p⁺-CdS and n⁺-ZnS as the contacts for hole and electron carrier collection, respectively. This junction has the same preferred features as illustrated in the a-Si:H cell, including carrier band offsets “ΔUᵥ and ΔU_{c}”, Fermi levels located within the WGS band edges and crossing through the band edges of i-CdTe at each interface. Most significantly, the cell of FIG. 3 should exhibit a larger built-in potential and lower recombination rates when compared to conventional CdTe cells, leading to an overall better photoelectric conversion efficiency.

The semiconductor arrangement illustrated in FIG. 3 is in contrast to prior art designs for CdTe solar cells, where conventionally p-CdTe is contacted at the front-side with n-CdS and at the rear with p-ZnTe (as described for example in U.S. Pat. No. 5,909,632 to Gessert). These contact semiconductors are preferred in convention designs due to the minimal carrier band offsets with CdTe at the contact interfaces. An additional distinguishing feature of conventional CdTe cells is the change in carrier type at the front contact from p-CdTe to n-CdS. Conversely, the invention's preferred arrangement is for an all-intrinsic absorber, where there is no change in carrier type at the interface.

### EXAMPLE 3

### Crystalline Silicon Absorber

FIG. 4 is an equilibrium band diagram illustration of the relevant sections of a solar cell using lightly doped, crystalline silicon as the active absorber. The cell uses p⁺-ZnO (U.S. Pat. No. 6,908,782 “High carrier concentration p-type transparent conducting oxide films”) and n⁺-ZnS WGS contacts as the hole and electron carrier collectors, respectively. This junction again incorporates carrier band offsets “ΔUᵥ and ΔU_{c}” at each contact interface and may be symbolized as “P⁺-p-n-N⁺”. In contrast to the examples given above, the active absorber contains regions where the equilibrium carrier concentrations are both depleted (across the Si p-n junction) and accumulated (at the two contacts). In solar cell applications, crystalline silicon is typically made at least 50 microns thick to give near complete absorption of sunlight. Because of this, the total silicon thickness is not shown to scale in the figure in an attempt to better illustrate the features of the novel front and rear contacts.

This cell construction is similar to conventional crystalline cells with the exception of the contacts. It is notable that the total built-in potential across the silicon is equal to the silicon band gap and this potential drop is shared between both the depleted and accumulated regions. Whereas in a conventional silicon cell the built-in potential is limited to that created by the p-n depletion zone. Silicon solar cells also conventionally exhibit a rather large reduction in output with increasing temperature and this is believed to be primarily due to a reduction of the built-in potential across the p-n junction. It is anticipated that as the temperature of the cell shown in FIG. 4 rises, the total built-in potential will remain constant. An increasing proportion of the built-in potential will shift into the accumulation regions in compensation for a corresponding loss of potential across the p-n depletion zone. Thus, the cell of FIG. 4 should prove to be more efficient at all temperatures when compared to a conventional design, and most particularly at elevated temperatures.

The principle and mode of operation of this invention have been described in its preferred embodiments. However, it should be noted that this invention may be practiced otherwise than as specifically illustrated and described without departing from its scope. Numerous alterations and modifications of the basic template outlined above are possible. Some of these possible variations are listed below.

The tunneling contacts may be used on only one side of the absorber. For instance the rear n⁺-ZnS/i-a-Si:H contact in Example 1 may substituted with a conventional n-type a-Si:H layer. Where feasible, the use of tunneling junctions on both sides is preferred as this will generally produce the largest electric field strength in the absorber.

More than a single absorber may be placed between the contacts. For example, varying the absorber composition can produce graded band gaps (e.g. varying the Ge content of an a-Si/Ge:H alloy) and this can be used to create an additional force for the extraction of photogenerated carriers by providing a downhill path with respect to carrier potential energy.

The tunnel contact semiconductors are described as being wide bandgap. This is preferred because wide bandgap semiconductors have a lower intrinsic carrier concentrations than the 1.0-1.7 eV gap semiconductors that are suitable as absorbers. A lower intrinsic carrier concentration will usually improve the cell output voltage and conversion efficiency. However, the tunneling contacts need not be wide-gap. A thin insulator or intrinsic semiconductor may be placed between a WGS and the absorber.

What is claimed is:

1. A photovoltaic device comprising a layer of a semiconductor light absorber, a conducting means on each side of said absorber for extraction of electrical energy from the absorber into an external circuit, and a transparent window on the front-side of said absorber to permit external light to impinge upon the absorber, said conducting means further comprising at least one semiconductor contact being disposed adjacent to said absorber, and said contact having: (a) a near degenerate or greater concentration of charge carriers, and (b) said carriers having a potential energy substantially greater than the same carrier type in the absorber, whereby an accumulation barrier is formed at the absorber surface to permit a facile extraction of charge by a tunneling assisted mechanism.

2. The device of claim 1, wherein said absorber is selected from a group including mono- and poly-crystalline Si, CdTe, amorphous Si:H alloys, CIGS alloys and GaAs alloys.

3. The device of claim 2, wherein said absorber further is substantially free of dopants.

4. The device of claim 2, wherein said contact semiconductor has a bandgap larger than 1.8 eV.

5. The device of claim 2, wherein said contact semiconductor has a concentration of charge carriers sufficient to place the Fermi level within 5 kT of the band edge.

6. The device of claim 5, wherein said contact semiconductor has a bandgap larger than 2.4 eV.

7. The device of claim 3, wherein said absorber is comprised of amorphous silicon hydride alloys.

8. The device of claim 2, wherein said contact semiconductor is present on both sides of said absorber layer.

9. A method for photoelectric energy conversion comprising, irradiating a semiconductor light absorber to alter said absorber's carrier chemical potentials, and providing for an electrical transporting means for moving charge from said absorber to an external circuit through an accumulation barrier located on at least one surface of said absorber, in response to the altered carrier chemical potential within said absorber.

10. The method of claim 9, wherein the absorber is selected from a group including mono- and poly-crystalline Si, CdTe, amorphous Si:H alloys, CIGS alloys and GaAs alloys.

11. The device of claim 10, wherein said absorber further is substantially free of electrically-active dopants.

12. The device of claim 11, wherein said absorber is comprised of amorphous silicon hydride alloys.

13. The device of claim 10, wherein said contact semiconductor is present on both sides of said absorber layer.

14. A method of increasing the built-in field strength of a solar cell, said solar cell incorporating a semiconductor as the photoactive absorber, said method comprising:
incorporating a semiconductor contact on a surface of said absorber during the fabrication thereof, said contact having excess carrier potential relative to said photoactive absorber, and incorporating said contact with dopants in an amount sufficient to produce a substantial charge accumulation within said absorber.

15. The method of claim 14, wherein the absorber is selected from a group including mono- and poly-crystalline Si, CdTe, amorphous Si:H alloys, CIGS alloys and GaAs alloys.

16. The device of claim 15, wherein said absorber further is substantially free of dopants.

17. The device of claim 16, wherein said absorber is comprised of amorphous silicon hydride alloys.
